(19) United States
(12) Patent Application Publication
(10) Pub. No.: US 2025/0167046 A1
(43) Pub. Date: May 22, 2025

(54) VIAS WITH SELECTED GRAIN DISTRIBUTION

(71) Applicant: Taiwan Semiconductor Manufacturing Company, Ltd., Hsinchu (TW)

(72) Inventors: Chia-Pang Kuo, Taoyuan (TW); Tzu-Hung Yang, Hsinchu (TW); I-Hsin Tseng, Hsinchu (TW); Jung-Hsuan Su, Taipei (TW); Wei Hsiang Chan, Hsinchu (TW); Chi-Feng Lin, Hsinchu (TW)

(73) Assignee: Taiwan Semiconductor Manufacturing Company, Ltd., Hsinchu (TW)

(21) Appl. No.: 18/514,410

(22) Filed: Nov. 20, 2023

(51) Int. Cl. H01L 21/768; H01L 23/00; H01L 23/48; H01L 23/522; H01L 23/532

(52) U.S. Cl. CPC H01L 21/76883; H01L 21/76816; H01L 21/76831; H01L 21/76844; H01L 21/76846; H01L 21/76871; H01L 21/76885; H01L 21/76898; H01L 23/481; H01L 23/5226; H01L 23/53238; H01L 24/04; H01L 24/05; H01L 24/06; H01L 24/13; H01L 24/14; H01L 2224/0401; H01L 2224/05573; H01L 2224/06181; H01L 2224/13025; H01L 2224/13144; H01L 2224/13147; H01L 2224/13155; H01L 2224/14181

(57) ABSTRACT

Conductive vias, semiconductor devices with conductive vias, and methods for fabricating semiconductor devices are provided. A conductive via includes a first end and a second end; a first portion adjacent to the first end; a second portion adjacent to the second; and a middle portion located between the first portion and the second portion, wherein the conductive via is comprised of metal grains, the metal grains in the first portion have a first grain size; the metal grains in the second portion have a second grain size; the metal grains in the middle portion have a third grain size; the first grain size is greater than the third grain size; and the second grain size is greater than the third grain size.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components by continual reductions in minimum feature size, which allow more components to be integrated into a given area. However, as the minimum features sizes are reduced, additional problems arise that should be addressed.

Among the efforts for reducing the size of integrated circuits and reducing RC delay, three-dimensional integrated circuit (3DIC) and stacked dies are commonly used. Conductive through-substrate vias (TSVs) are thus used in 3DIC and stacked dies. For example, conductive TSVs are often used to connect the integrated circuits on a die to the backside of the die. In addition, conductive TSVs are also used to provide short grounding paths for grounding the integrated circuits through the backside of the die, which may be covered by a grounded metallic film.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method, in accordance with some embodiments.

FIGS. 2 through 8 are cross-sectional views of intermediate stages in the manufacturing of a wafer comprising a conductive TSV and deep conductive vias connected to the conductive TSV in accordance with various embodiments.

FIG. 9 illustrates a wafer comprising a conductive TSV and deep conductive vias, wherein a metal line connecting the conductive TSV and the deep conductive vias is formed in a process step separated from the process step for forming the conductive TSV and the deep conductive via.

FIG. 10 illustrates a wafer comprising a conductive TSV and deep conductive vias, wherein the conductive TSV extends through a substrate that is substantially free from an integrated circuit device.

FIGS. 11 through 22 are cross-sectional views of intermediate stages in the fabrication of a wafer comprising a conductive TSV and deep conductive vias connected to the conductive TSV in accordance with various embodiments.

FIG. 23 is a graph illustrating the distribution of grain sizes within a top portion, a middle portion, and a bottom portion of a conductive TSV in accordance with various embodiments.

FIG. 24 is a cross-sectional view of a portion of layers deposited on a trench sidewall, such as at the intermediate stage of FIG. 16.

FIG. 25 is a cross-sectional view of a portion of layers forming an alloy, such as after the anneal process of FIG. 20.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices with through-substrate vias (TSVs), also sometimes known as through-silicon vias (TSVs) when formed in a silicon substrate. Methods described herein may be easily integrated into the current process flow.

Certain embodiments herein relate to three-dimensional integrated circuit (3DIC) applications built by vertically stacking different chips or wafers together into a single package. For example, in 3DIC application, through-substrate vias (TSVs) may be applied to chip-to-chip stacking or chip-to-interposer stacking for vertical electrical signal connection. Certain embodiments herein optimize stress and voiding distribution in TSVs to obtain 100% yield during fabrication. For example, a selected metallization process for forming the conductive TSVs may be used to achieve a Large-Small-Large (L-S-L) grain distribution along the height or depth of the TSVs, i.e., top to bottom (or bottom to top). Further such grain distribution may be symmetrical.

In some embodiments, methods are provided to obtain Large-Small-Large (LSL) grain distribution in conductive structures, such as in conductive vias like conductive TSVs. Methods may utilize a metallization process for filling a trench including forming an outer adhesive layer with a thickness gradient, forming an outer barrier layer with a constant thickness on the outer adhesive layer, forming an inner adhesive layer with a thickness gradient on the outer barrier layer, removing the inner adhesive layer from the trench bottom surface, and thereafter forming a seed layer before filling the trench with a conductive fill and performing an anneal process to form an alloy with grains.

In some embodiments, an anneal process used to form the TSVs may result in the diffusion of small voids to a middle or midlevel height of the TSVs, rather than to the bottom of the TSVs. Specifically, voids move from the top of the TSVs downward to the midlevel, while voids move from the bottom of the TSVs upward to the midlevel.

Further, the conductive TSV material forms into relatively larger grains at the top and bottom of the conductive TSVs and forms into relatively smaller grains at the midlevel of the conductive TSVs. Because voids migrate from high stress to low stress (i.e., from large grains to smaller grains or to the TSV top surface or bottom surface), there will be no void aggregation at the interface between the top of the conductive TSV and the top die redistribution layer (RDL), and there will be no void aggregation at the interface between the bottom of the conductive TSV and the bottom die redistribution layer (RDL). Rather, most of the voids diffuse toward the midlevel of the conductive TSV. As a result, there is less void aggregation at the TSV top surface or TSV bottom surface.

Embodiments herein avoid or reduce formation of large voids, sidewall delamination, conductive TSVs end protrusion, and TSV/die interface voids. Embodiments herein improve the grain distribution of the conductive material, such as copper and/or a titanium copper alloy, to form conductive TSVs with high thermal stability.

Embodiments of the present disclosure offer advantages over the existing art, though it is understood that other embodiments may offer different advantages, not all advantages are necessarily discussed herein, and no particular advantage is required for all embodiments.

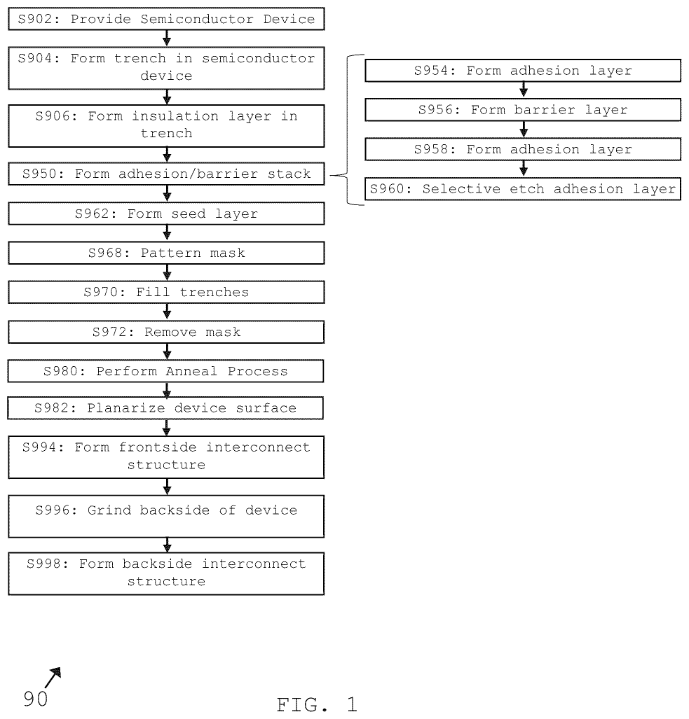

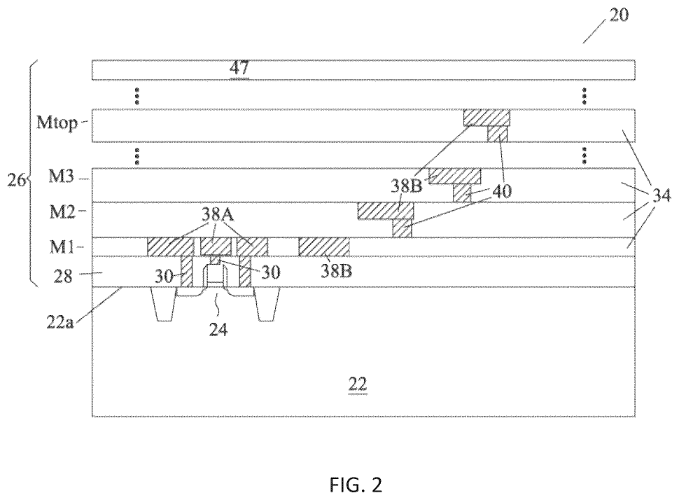

For purposes of the discussion that follows, FIG. 1 provides a flow chart for a method 900 for fabricating a semiconductor device during a semiconductor fabrication process. Method 900 is described below with reference to FIGS. 2-10 and FIGS. 11-22 which illustrate the semiconductor device at various stages of fabrication according to method 900.

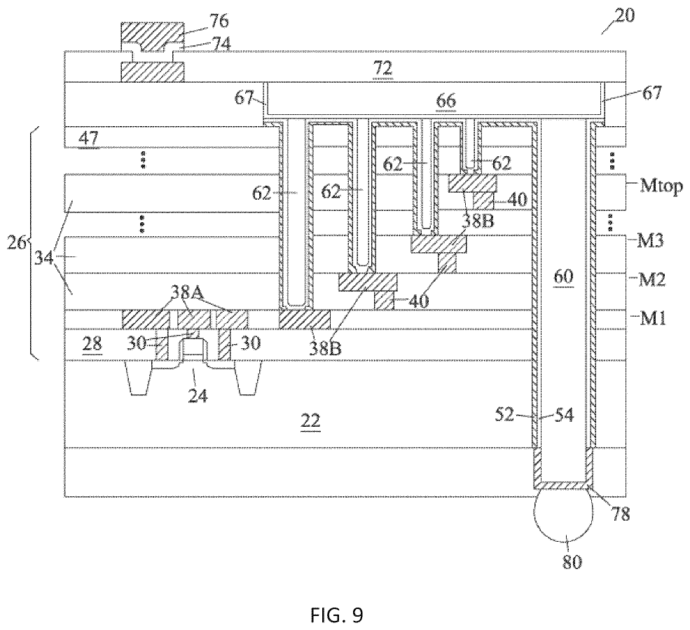

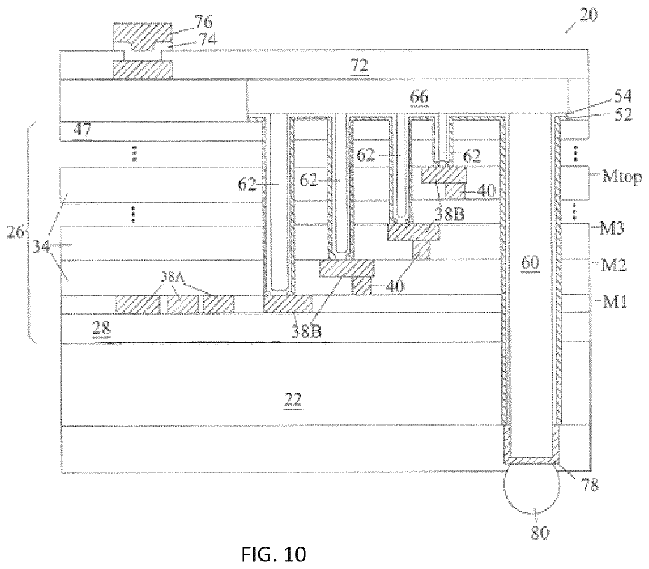

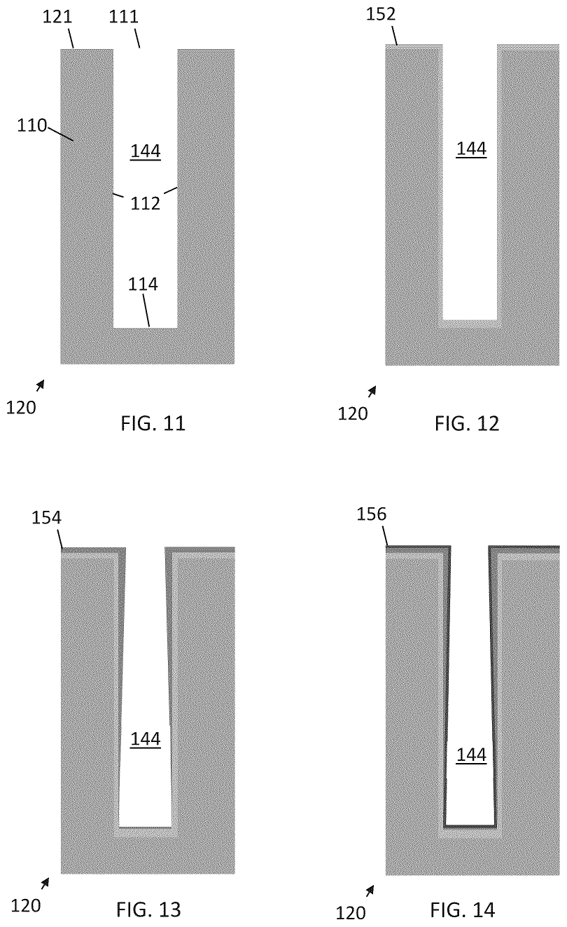

FIGS. 2 through 8 are cross-sectional views of intermediate stages in the manufacturing of a wafer comprising a conductive TSV and deep conductive vias connected to the conductive TSV in accordance with various embodiments. FIG. 9 illustrates a wafer comprising a conductive TSV and deep conductive vias, wherein a metal line connecting the conductive TSV and the deep conductive vias is formed in a process step separated from the process step for forming the conductive TSV and the deep conductive via. FIG. 10 illustrates a wafer comprising a conductive TSV and deep conductive vias. FIGS. 11-22 are cross-sectional views of intermediate stages for forming a conductive TSV within a trench.

Referring to FIG. 2, method 900 includes, at operation S902, providing a semiconductor device 20, which includes substrate 22 and integrated circuits 24 (symbolized by a transistor) therein. In accordance with various embodiments, device 20 is a wafer comprising active integrated circuit devices 24 such as transistors. Substrate 22 may be a semiconductor substrate, such as a bulk silicon substrate, although it may be formed of other semiconductor materials such as silicon germanium, gallium arsenide, and/or the like. Semiconductor devices such as transistors (a symbolized by transistor 24) may be formed at the front surface 22a of substrate 22. Interconnect structure 26 is formed on the front side of substrate 22. Interconnect structure 26 may include inter-layer dielectric (ILD) 28 (in which the electrodes of transistor is located) and contact plugs 30 in ILD 28, wherein contact plugs 30 may be formed of tungsten or other metallic materials.

Furthermore, interconnect structure 26 include inter-metal dielectrics (IMDs) 34, and metal lines/pads 38 (including 38A and 38B) and vias 40 in IMDs 34. IMDs 34 may be formed of low-k dielectric materials having low k values, for example, lower than about 2.5, or even lower than about 2.0. Interconnect structure 26 may include a bottom metallization layer (commonly known as M1) and a top metallization layer (commonly known as Mtop), and a plurality of metallization layers therebetween, including the metallization layer (M2) immediately over M1, the metallization layer (M3) immediately over M2, and the like. The metal features in interconnect structure 26 may be electrically coupled to semiconductor devices 24. Metal lines/pad 38 and vias 40 may be formed of copper or copper alloys, and may be formed using the well-known damascene processes. Metal lines/pads 38 include metal lines 38A and metal pads 38B, with metal pads 38B being used for landing the subsequently formed deep vias.

Interconnect structure 26 may further include one or more passivation layer(s) 47 that is immediately over metallization layer Mtop. Passivation layer 47 may be a non-low-k dielectric layer, and may be formed of silicon oxide, silicon nitride, un-doped silicate glass, polyimide, or the like. Further, additional metal lines/pads and vias (not shown) may be formed in passivation layer(s) 47.

In alternative embodiments, such as in the example of FIG. 10, device 20 is an interposer wafer, and is substantially free from integrated circuit devices, including active devices such as transistors and diodes formed therein. In these embodiments, substrate 22 may be formed of a semiconductor material or a dielectric material. The dielectric material may be silicon oxide, an organic material such as polyimide, a hybrid material such as molding compound, glass, or the like. Furthermore, interposer device 20 may include, or may be free from, passive devices such as capacitors, resistors, inductors, varactors, and/or the like.

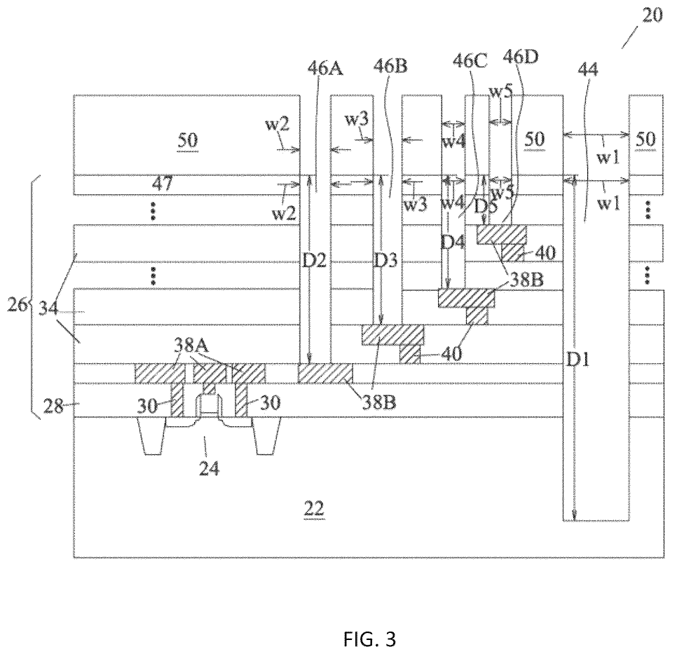

Referring to FIG. 3, after the formation of interconnect structure 26, which may or may not include layer(s) 47, method 900 may include, at operation S904, forming trenches, such as TSV trench 44 and deep via trenches 46 (including 46A, 46B, 46C, 46D, and possibly more that are not illustrated). In an embodiment, photo resist 50 is formed and patterned. TSV trench 44 and deep via trenches 46 are then formed simultaneously by etching. TSV trench 44 extends into substrate 22, while deep via trenches 46 stop at respective metal pads 38B, with metal pads 38B exposed through deep vias 46. Further, the formation of deep via trenches 46 may stop at metal pads 38B in any one of different metallization layers ranging from M1 through Mtop in any desirable combination.

In an embodiment, pattern loading effect is used to form TSV trench 44 and deep via trenches 46, which have different depths, simultaneously. It is observed that when certain via openings are formed, the via openings having greater horizontal sizes may have greater depths than the via openings having smaller sizes, even if they are formed by a same etching process. As a result of the pattern loading effect in the etching process, and also due to the size difference between TSV trench 44 and deep via trenches 46, the resulting TSV trench 44 and deep via trenches 46 will have different depths. With properly adjusted horizontal sizes W1 through W5, when the desirable depth D1 of TSV trench 44 is reached, desirable depths D2, D3, D4, D5, and the like are also reached. This may reduce the undesirable over-etching of metal pads 38B, and hence the undesirable damage to metal pads 38B may be minimized. Accordingly, the horizontal dimension W1 (which may be a diameter or a length/width, depending on the shape of TSV trench 44) of TSV trench 44 is greater than horizontal dimensions W2, W3, W4, and W5 of deep via trenches 46. In an embodiment, a ratio of W1/W2 (or W1/W3, W1/W4, and so on) may be greater than about 1.5, greater than about 5, or even greater than about 100. Further, depth D1 of TSV trench 44 is greater than depth D2 of deep via trenches 46. In an embodiment, a ratio of D1/D2 (or D1/D3, D1/D4, and so on) may be greater than about 5, or even greater than about 5,000. Further, in the illustrated embodiments, W2 may be greater than W3 with ratio W2/W3 being greater than about 1.2, W3 may be greater than W4 with ratio W3/W4 being greater than about 1.2, and W4 may be greater than W5 with ratio W4/W5 being greater than about 1.2.

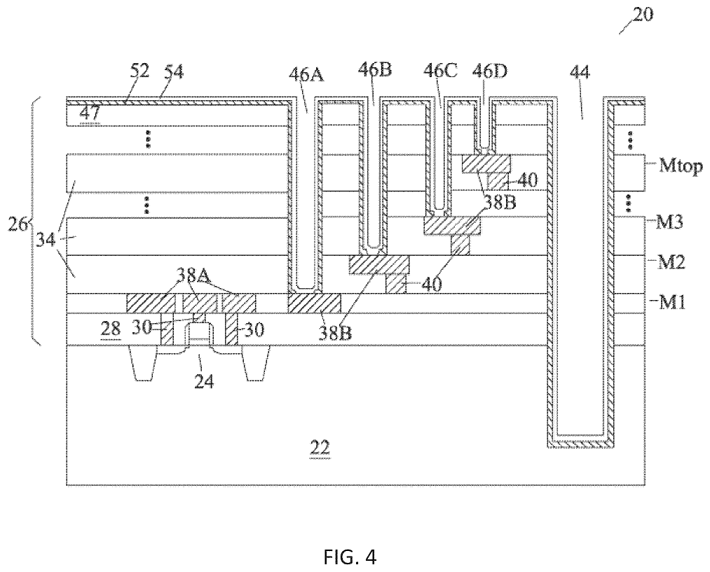

Referring to FIG. 4, method 900 may continue at operation S906 with forming an insulation layer 52. For example, the insulation layer 52 may be deposited and patterned, and metal pads 38B may be exposed through the openings in insulation layer 52.

Method 900 may continue at operation S950 with forming an adhesion/barrier layer stack 54.

Method 900 may continue at operation S962 with forming a thin seed layer (not shown in FIG. 4). For example, the seed layer may be blanket formed over stack 54. The materials of the seed layer may include copper or copper alloys, and metals such as silver, gold, aluminum, and combinations thereof may also be included. In an embodiment, the seed layer is formed of sputtering. In other embodiments, other commonly used methods such as electro or electroless plating may be used.

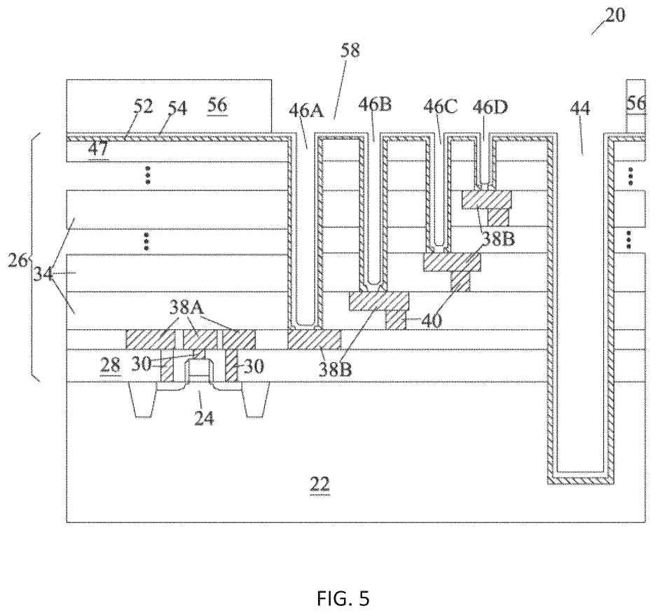

Referring to FIG. 5, method 900 may include, at operation S968, patterning a mask 56 on the previously formed structure. In an embodiment, mask 56 comprises a photo resist, for example. In an exemplary embodiment, the resulting conductive TSV needs to be connected to metal pads 38B. Accordingly, opening 58 is formed in mask 56, exposing TSV trench 44 and deep via trenches 46.

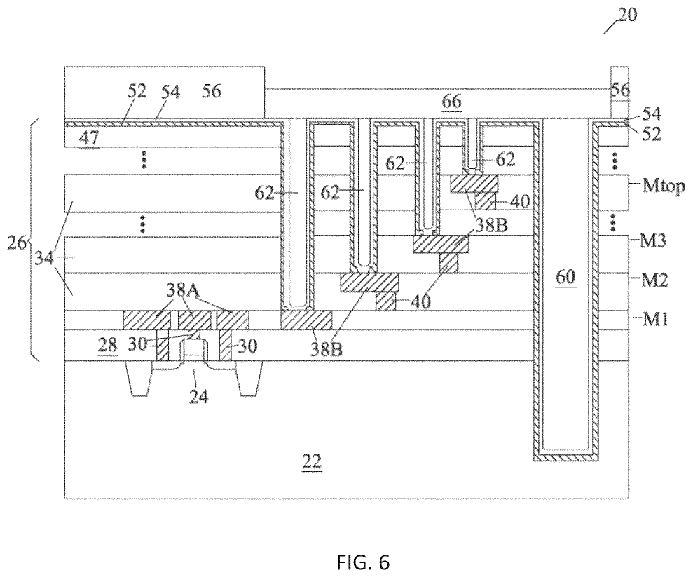

In FIG. 6, method 900 includes, at operation S970, filling trenches 44, 46, and 58 with a metallic material, and forming a conductive via 60, such as a conductive TSV 60 in TSV trench 44, deep conductive vias 62 in deep via trenches 46, and metal line 66 in the opening 58. In various embodiments, the filling material includes copper or copper alloys, although other metals, such as aluminum, silver, gold, and combinations thereof, may also be used. The formation methods may include printing, electro plating, electroless plating, and the like. In the same deposition process in which TSV trench 44 is filled with the metallic material, the same metallic material may also be filled in opening 58, forming metal line 66, which is also referred to a redistribution line (RDL).

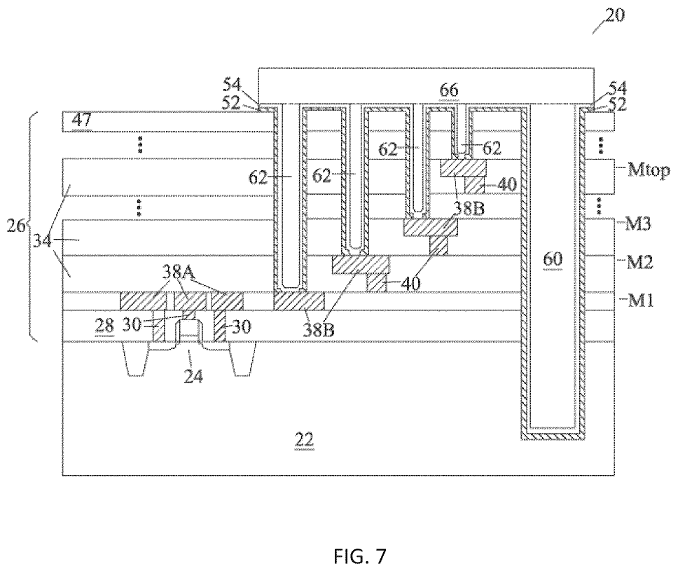

Next, as is shown in FIG. 7, method 900 includes removing mask 56 at operation S972.

Method 900 may include performing an anneal process at S980.

Method 900 may continue at operation S982 with planarizing the upper device surface.

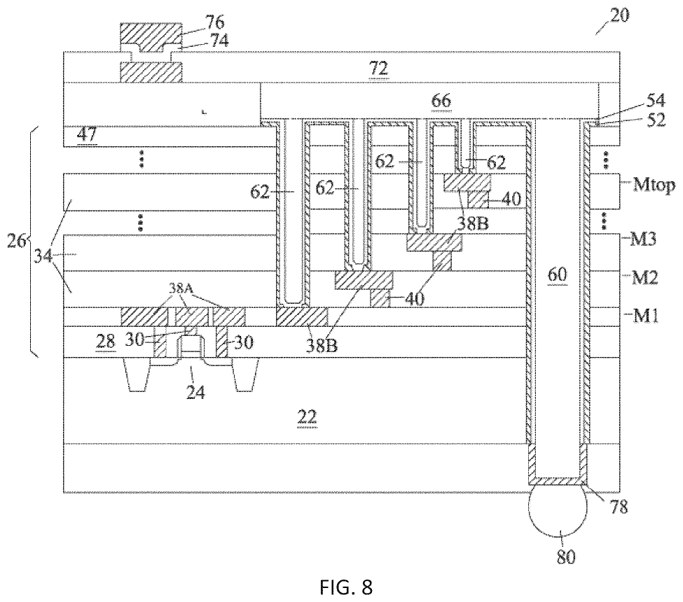

In FIG. 8, method 900 includes, at operation S994, forming a frontside interconnect structure, such as including redistribution layers (RDLs), passivation layer(s) 72 and under-bump metallurgy (UBM) 74, and metal bump 76. Metal bump 76 may be a solder bump, a copper bump, and may include other layers/materials such as nickel, gold, solder, and/or the like.

In FIG. 8, method 900 includes, at operation S996, grinding the backside of device 20, so that conductive TSV 60 is exposed. Further, method 900 includes, at operation S998, forming a backside interconnect structure, which may include UBM 78 and bond pad/metal bump 80, on the backside of device 20. Further, a backside interconnect structure (not shown) including a plurality of redistribution layers may be formed between, and electrically coupling, conductive TSV 60 and metal bump 80.

FIG. 9 illustrates an alternative embodiment. This embodiment is essentially the same as the embodiment shown in FIG. 8, except that metal line 66 is not formed in the same process as forming conductive TSV 60 and deep vias 62. In the embodiment of FIG. 9, after the formation of the structure shown in FIG. 4, TSV trench 44 and deep via trenches 46 are filled, followed by a planarization process such as a chemical mechanical polish (CMP) to remove excess metal, and hence conductive TSV 60 and deep vias 62 are formed. After the CMP process, conductive TSV 60 and deep vias 62 are electrically disconnected from each other. Next, metal line 66 is formed to electrically couple conductive TSV 60 to deep vias 62. In the resulting structure, diffusion barrier layer 67 separates conductive TSV 60 and deep vias 62 from metal line 66. Diffusion barrier layer 67 may comprise titanium, titanium nitride, tantalum, tantalum nitride, or the like. In the structure shown in FIG. 8, however, no diffusion barrier layer is formed to separate conductive TSV 60 and deep vias 62 from metal line 66.

Although in the illustrated figures, device dies including semiconductor devices are used as examples, the teaching provided by the embodiments may be readily applied to interposers comprising no integrated circuits such as transistors, resistors, diodes, capacitors, and/or the like. Similarly, by using the embodiments, deep vias can be formed on interconnect structures on either one, or both, of the front-side interconnect structure and backside interconnect structure, with the deep vias connected to TSVs in interposers.

FIGS. 11-22 illustrate an embodiment for forming a conductive interconnection structure 200 such as a conductive via 200, such as the conductive TSV 60, formed in the embodiment of FIGS. 2-10.

FIG. 11 illustrates a device 120 after operation S904, where a trench 144, similar to TSV trench 44 from the embodiment of FIGS. 2-10, has been formed. Specifically, a trench 144 is etched into the device layers, generally indicated by reference number 110. The device layers 110 may include various dielectric layers or substrate. In FIG. 11, the trench 144 extends from an upper device surface 121 through device layers and is formed with opposite trench sidewalls 112 and a trench bottom surface 114. As shown, the trench 144 has an opening 111 at the upper device surface 121.

FIG. 12, illustrates the device 120 after performing operation S906, forming an insulation layer 152 in the trench 144. For example, the insulation layer 152 may be silicon oxide, or another suitable insulating material. In some embodiments, the insulation layer 152 is deposited conformally and is formed along the upper device surface 121, the trench sidewalls 112, and the trench bottom surface 114.

FIGS. 13-16 illustrate an embodiment for forming the adhesion/barrier stack 54 of operation S950. Specifically, as shown in FIG. 13, method 900 may continue at optional operation S954 with forming an adhesion layer 154 over the insulation layer 152. In some embodiments, the adhesion layer 154 is titanium (Ti). In other embodiments, the adhesion layer 154 may be selected from commonly used materials such as titanium, titanium nitride, tantalum, tantalum nitride, and combinations thereof. In some embodiments, the adhesion layer 154 is deposited by physical vapor deposition (PVD). As shown, the adhesion layer 154 is formed over the upper device surface 121, over trench sidewalls 112, and over trench bottom surface 114. Due to the deposition process, the adhesion layer 154 is generally formed with a larger relative thickness over the horizontal surfaces, i.e., over the upper device surface 121 and over the trench bottom surface 114, as compared to the vertical surfaces of the trench sidewalls 112. Further, due to the deposition process, the adhesion layer 154 is generally formed on the trench sidewalls 112 with a decreasing thickness from the upper device surface 121, where the adhesion layer thickness is greatest, toward the trench bottom surface 114, where the adhesion layer sidewall thickness is smallest, and may be zero.

For example, in an embodiment the adhesion layer 154 is formed with a maximum lateral or sidewall thickness on each trench sidewall 112 at the opening 111 of the trench 144 that is from twenty-five times to sixty times greater, such as fifty times greater, than a minimum lateral or sidewall thickness on each trench sidewall 112 adjacent to the trench bottom surface 114. For example, the maximum sidewall thickness of the adhesion layer 154 may be 250 nanometers (nm) and the minimum sidewall thickness of the adhesion layer 154 may be 5 to 10 nanometers (nm). In such an example, the vertical thickness of the adhesion layer 154 over the trench bottom surface 114 may be 50 nanometers (nm).

In FIG. 14, method 900 may continue at operation S956 with forming a barrier layer 156 over the adhesion layer 154. In some embodiments, the barrier layer 156 is titanium nitride (TiN). In other embodiments, the barrier layer 156 may be selected from commonly used materials such as titanium, titanium nitride, tantalum, tantalum nitride, and combinations thereof. In some embodiments, the barrier layer 156 is deposited by chemical vapor deposition (CVD). As shown, the barrier layer 156 is formed over the upper device surface 121, over trench sidewalls 112, and over trench bottom surface 114. In some embodiments, the barrier layer 156 is conformally deposited with a generally same thickness over the upper device surface 121, trench sidewalls 112, and trench bottom surface 114.

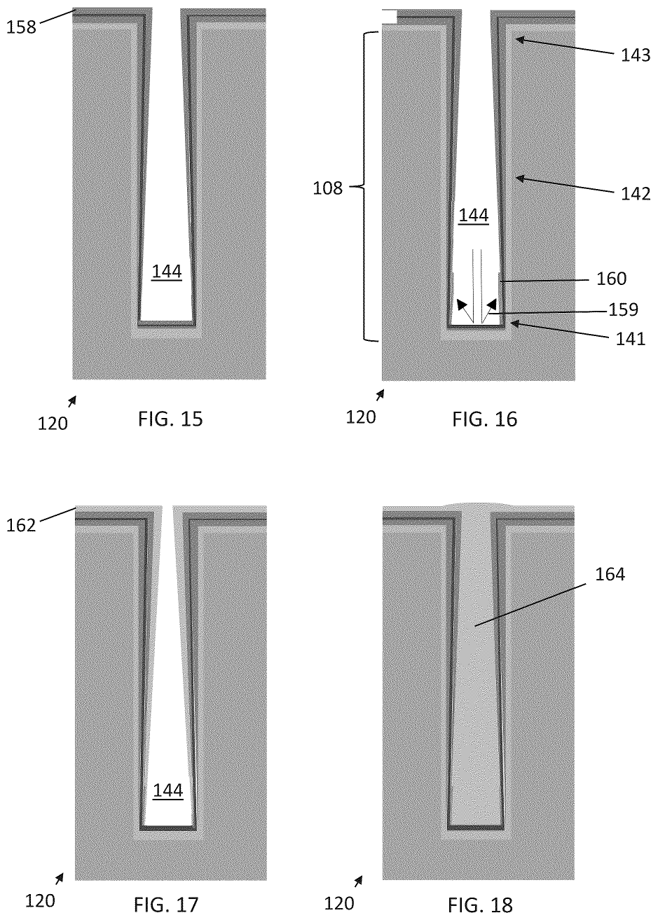

In FIG. 15, method 900 may continue at operation S958 with forming an adhesion layer 158 over the barrier layer 156. In some embodiments, the adhesion layer 158 is titanium (Ti). In other embodiments, the adhesion layer 158 may be selected from commonly used materials such as titanium, titanium nitride, tantalum, tantalum nitride, and combinations thereof. In some embodiments, the adhesion layer 158 is deposited by physical vapor deposition (PVD). As shown, the adhesion layer 158 is formed over the upper device surface 121, over trench sidewalls 112, and over trench bottom surface 114. Due to the deposition process, the adhesion layer 158 is generally formed with a larger relative thickness over the horizontal surfaces, i.e., over the upper device surface 121 and over the trench bottom surface 114, as compared to the more vertical surfaces of the trench sidewalls 112. Further, due to the deposition process, the adhesion layer 158 is generally formed on the trench sidewalls 112 with a decreasing thickness from the upper device surface 121, where the adhesion layer thickness is greatest, toward the trench bottom surface 114, where the adhesion layer sidewall thickness is smallest, and may be zero.

For example, in an embodiment the adhesion layer 158 is formed with a maximum lateral or sidewall thickness on each trench sidewall 112 at the opening 111 of the trench 144 that is from twenty-five times to sixty times greater, such as fifty times greater, than a minimum lateral or sidewall thickness on each trench sidewall 112 adjacent to the trench bottom surface 114. For example, the maximum sidewall thickness of the adhesion layer 158 may be 250 nanometers (nm) and the minimum sidewall thickness of the adhesion layer 158 may be 5 to 10 nanometers (nm). In such an example, the vertical thickness of the adhesion layer 158 over the trench bottom surface 114 may be 50 nanometers (nm).

In FIG. 16, method 900 may continue at operation S960 with performing an etch process to remove the adhesion layer 158 from over the trench bottom surface 114. For example, a dry etch such as a plasma etch process may be performed. In some embodiments, the etch process may use argon without reactive ions. In some embodiments, the etch process is a sputter etching process. For example, ions, such as argon ions, may bombard the adhesion layer 158 over the trench bottom surface 114. The etch process may be highly directional such that it may be focused on the trench bottom surface 114.

As a result of the etch process, the adhesion layer 158 is removed from over the trench bottom surface 114. Specifically, the barrier layer 156 is exposed at the trench bottom surface 114. Further, the removed adhesion layer may form a gaseous material that is then deposited on the trench sidewalls 112, as indicated by arrows 159. As a result, coverage of the adhesion layer material over the lower portions of the trench sidewalls 112 may be increased. It is noted that enhanced coverage of the lower portions of the trench sidewalls 112 by the adhesion layer material, such as titanium, may prevent copper delamination.

FIG. 16 illustrates the formation of a metallization stack or structure including adhesion layer 154, barrier layer 156, and adhesion layer 158 configured to provide a final conductive TSV with a desired grain distribution. As shown, the layers 154, 156 and 158 are provided with different thicknesses at different locations of the trench 144. For example, layers 154, 156 and 158 may be provided with different thicknesses over the trench bottom surface 114, at a bottom sidewall location 141 adjacent the trench bottom surface 114, at a top sidewall location 143 adjacent the opening 111 of the trench, and at a midlevel or middle height sidewall location 142 located between the top sidewall location 143 and bottom sidewall location 141. In some embodiments, the middle height sidewall location 142 may be equidistant from the top sidewall location 143 and bottom sidewall location 141. In other embodiments, the middle height sidewall location may be located at a height over the trench bottom surface 114 equal to 20%, 30%, 40%, 50%, 60%, 70%, or 80% of the total height 108 of the trench 144.

In FIG. 17, method 900 may continue at operation S962 with forming a seed layer 162 over the upper device surface 121 and in the trench 144. The seed layer 162 may be copper. In some embodiments, the materials of the seed layer may include copper or copper alloys, and metals such as silver, gold, aluminum, and combinations thereof may also be included.

In an embodiment, the seed layer 162 is formed by physical vapor deposition (PVD). Further, the seed layer 162 may be deposited with a selectivity toward forming over the material of the adhesion layer 158, e.g., titanium, as compared to the material of the barrier layer 156, i.e., titanium nitride. Thus, the seed layer may be formed with a greatest thickness over the adhesion layer 158 at the horizontal upper device surface 121, a smallest thickness, or a thickness of zero, over the barrier layer 156 at the trench bottom surface 114, and over the adhesion layer 158 at the trench sidewalls 112 with a decreasing thickness from the upper device surface 121, where the seed layer thickness is greatest, toward the trench bottom surface 114, where the seed layer sidewall thickness is smallest, and may be zero.

At FIG. 18, method 900 may continue at operation S970 with depositing conductive material 164 to fill the trench 144. In some embodiments, the conductive material 164 is a metallic material, such as copper. In various embodiments, the filling material 164 includes copper or copper alloys, although other metals, such as aluminum, silver, gold, and combinations thereof, may also be used. The formation methods may include printing, electro plating, electroless plating, and the like. For example, the conductive material 164 may be deposited by electrochemical deposition (ECD).

Generally, the conductive material 164 is formed with small grains during the deposition process. As used herein, a “small grain” has a maximum dimension of 0.5 micrometers (μm). In some embodiments, the small grains have a maximum dimension of 0.4 μm, 0.3 μm, 0.2 μm, or 0.1 μm. In some embodiments, at least 50 wt. %, at least 60 wt. %, at least 70 wt. %, at least 80 wt. %, at least 90 wt. %, at least 95 wt. %, or at least 99 wt. % of the conductive material 164 formed by small grains.

Because the adhesion layer 158 was previously removed from the trench bottom surface 114, the conductive material 164 directly contacts the barrier layer 156, such as titanium nitride, at the trench bottom surface 114. Along the trench sidewalls 112, the conductive material and/or seed layer 162 directly contacts the adhesion layer 158, such as titanium.

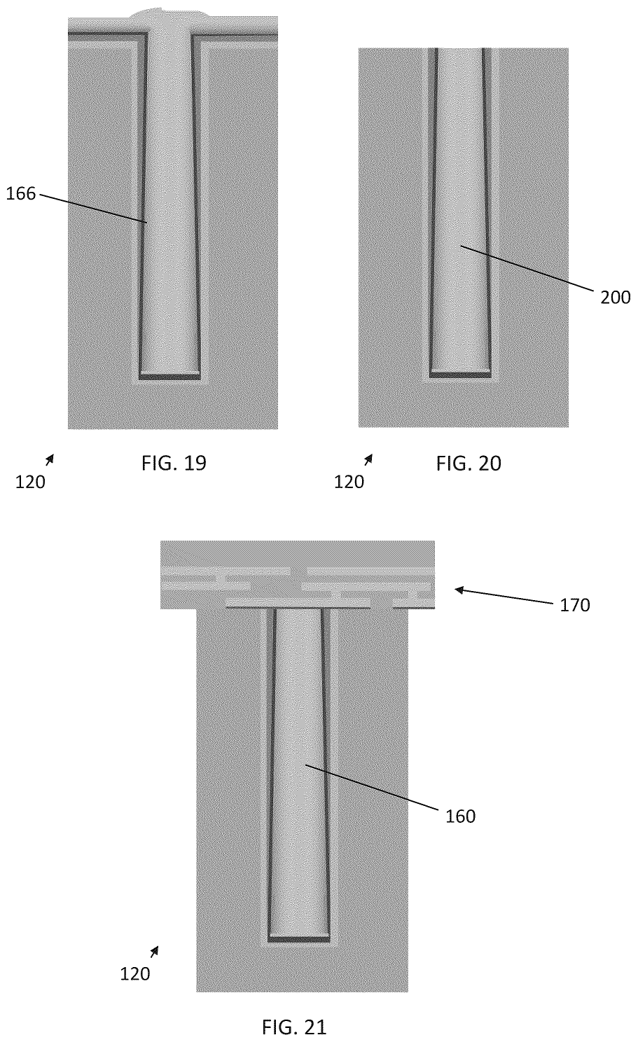

At FIG. 19, method 900 may continue at operation S980 with performing an anneal process. The anneal process may involve grain growth and stress release. Specifically, during the anneal process, conductive material 164, such as copper, is heated beyond its recrystallization temperature to release internal stresses and then is allowed to cool under controlled conditions. Thus, during the anneal process, grains of the conductive material 164 may grow. Also, voids may migrate from high stress locations to low stress locations, i.e., from large grains to small grains. Further, in regions where materials of the conductive material 164 and the adhesion layer 158 are adjacent, an alloy 166 may be formed. For example, a titanium-copper alloy 166 may form. It is noted that the seed layer 162 is formed between the conductive material 164 and the adhesion layer 158 or barrier layer 156. For purposes of simplicity, the following description discusses the conductive material 164, which may collectively refer to the separately-deposited seed layer 162 and conductive material 164. Further, in some embodiments, the seed layer 162 and conductive material 164 are the same material.

As noted above, before the anneal process, the conductive material 164 directly contacts the barrier layer 156 at the trench bottom surface 114, and the conductive material and/or seed layer 162 directly contacts the adhesion layer 158 along the trench sidewalls 112. Therefore, formation of the titanium-copper alloy may be greater along the trench sidewalls 112 than at the trench bottom surface 114.

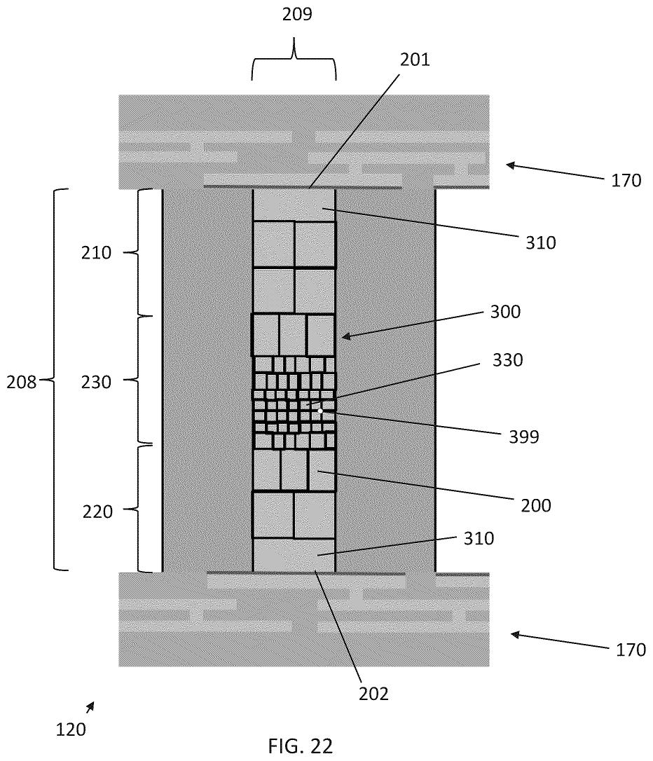

In embodiments herein, the conductive material 164 may form large grains in certain regions and may form small grains in certain regions, as is described below in relation to FIG. 22.

In FIG. 20, method 900 may continue at operation S982 with planarizing the upper device surface 121. Specifically, the material of the layers 152, 154, 156, 158, 162, and 164 located over the upper device surface 121 may be removed, such as by a chemical mechanical planarization (CMP) process. As a result, the conductive via 200 is formed and defined within the trench 144.

In FIG. 21, method 900 may at operation S994 continue with forming a frontside interconnect structure, including the forming of redistribution layers (RDLs) 170 over the conductive via 200.

At FIG. 22, method 900 may continue at operation S996 with grinding the backside of the device and removing the device layers 110 below the trench bottom surface 114, thereby opening the trench bottom surface 114. For example, a planarization process may be used to open the trench bottom surface 114. Further, the bottom end of the conductive TSV 200 may be polished.

At FIG. 22, method 900 may further continue at operation S998 with forming the backside interconnect structure, including redistribution layers (RDLs) 170, over the opened bottom end of the conductive TSV 200.

As shown in FIG. 22, the conductive TSV 200 has a top surface 201 and a bottom surface 202. The top surface 201 is distanced from the bottom surface by a vertical height 208, such as in a Z-direction. The vertical height 208 may be from 5 to 200 micrometers (μm). Further, the conductive TSV 200 has a lateral width or critical dimension in an X-direction perpendicular to the Z-direction. The lateral critical dimension 209 may be from 1 to 10 micrometers (μm). Thus, the conductive TSV 200 may have an aspect ratio (height/critical dimension) of from 5 to 20.

Further, the conductive TSV 200 includes a top portion 210 adjacent to the top surface 201, a bottom portion 220 adjacent to the bottom surface 202, and a middle portion 230, or midlevel, located between the top portion 210 and the bottom portion 220. Each portion 210, 220, and 230 may have a height equal to one-third of the total height 208.

FIG. 22 further illustrates the grains 300 that are formed within the conductive TSV 200 during the anneal process of operation S980. As shown, relatively large grains 310 are formed at the top and bottom portions 210 and 220. Further, relatively small grains 330 are formed at the middle portion 230. In some embodiments, the metal grains 310 in the first portion 210 have a first grain size, the metal grains 320 in the second portion 220 have a second grain size, and the metal grains 330 in the middle portion 230 have a third grain size, wherein the first grain size is greater than the second grain size and the third grain size, and wherein the second grain size is greater than the third grain size.

In some embodiments, a largest grain 310 in the first portion 210 defines a maximum grain size. In some embodiments, the maximum grain size is from 200 to 1000 nanometers (nm).

In some embodiments, the average grain size of grains 310 in the first portion 210 is greater than 0.5 of the maximum grain size. For example, the average grain size of grains 310 in the first portion 210 may be greater than 0.51, greater than 0.52, greater than 0.53, greater than 0.54, greater than 0.55, greater than 0.56, greater than 0.57, greater than 0.58, greater than 0.59, greater than 0.60, greater than 0.61, or greater than 0.62 of the maximum grain size. Further, the average grain size of grains 310 in the first portion 210 may be less than 0.8, less than 0.75, less than 0.74, less than 0.73, less than 0.72, less than 0.71, less than 0.70, less than 0.69, less than 0.68, less than 0.67, less than 0.66, less than 0.65, less than 0.64, less than 0.63, or less than 0.62 of the maximum grain size.

In some embodiments, the average grain size of grains 320 in the second portion 220 is greater than 0.5 of the maximum grain size. For example, the average grain size of grains 320 in the second portion 220 may be greater than 0.51, greater than 0.52, greater than 0.53, greater than 0.54, or greater than 0.55 of the maximum grain size. Further, the average grain size of grains 320 in the second portion 220 may be less than 0.8, less than 0.75, less than 0.7, less than 0.65, less than 0.64, less than 0.63, less than 0.62, less than 0.61, less than 0.60, less than 0.59, less than 0.58, less than 0.57, less than 0.56, or less than 0.55 of the maximum grain size.

In some embodiments, the average grain size of grains 330 in the middle portion 230 is less than 0.5 of the maximum grain size. For example, the average grain size of grains 330 in the middle portion 230 may be greater than 0.25, greater than 0.28, greater than 0.3, greater than 0.31, greater than 0.32, greater than 0.33, greater than 0.34, greater than 0.35, greater than 0.36, or greater than 0.37 of the maximum grain size. Further, the average grain size of grains 330 in the middle portion 230 may be less than 0.5, less than 0.49, less than 0.48, less than 0.47, less than 0.46, less than 0.45, less than 0.44, less than 0.43, less than 0.42, less than 0.41, less than 0.40, less than 0.39, less than 0.38, or less than 0.37 of the maximum grain size.

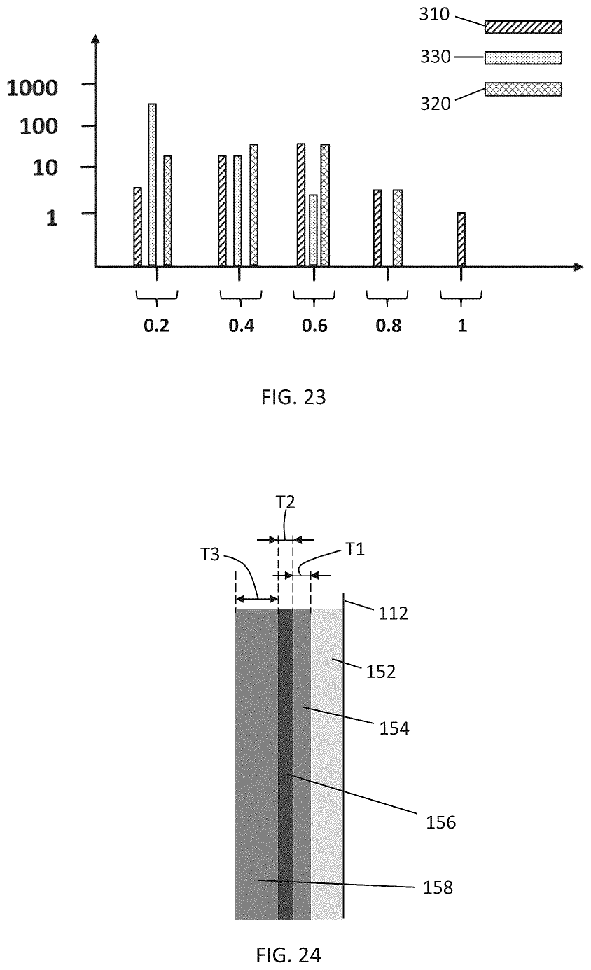

A grain size distribution graph is provided in FIG. 23. In the graph, the vertical axis is the number of grains on a logarithmic scale, and the horizontal axis is the grain size as a ratio of the maximum grain size (Gmax). As shown, one grain 310 in the top portion 210 has the maximum grain size, and no grains 320 or 330 have the maximum grain size. More than one grain 310 and more than one grain 320 has a size of 0.8 times the maximum grain size. More grains 330 have the smallest size of 0.2 times the maximum grain size.

Without being bound by the theory, it is believed that large grains 310 are formed in the top portion 210 due to the free surface, i.e., non-confined surface, over the opening of the trench 144 (as shown in FIG. 19). With a free surface, there is no confinement in at least one direction, allowing for larger grain growth.

Further, without being bound by the theory, it is believed that small grains 330 are formed in the middle portion 230 due to the large amount of titanium available for titanium-copper alloy formation from the titanium adhesion layer 158. For example, alloy formation from copper and titanium occurs at temperatures greater than 300° C.; therefore, in an anneal process performed at a temperature greater than less than 300° C., such as at 400° C., more titanium-copper is formed. In certain embodiments, the anneal process may be performed such that all of the titanium adhesion layer 158 is converted to titanium-copper alloy. With increased formation of titanium-copper alloy, the grain growth of copper may be suppressed and smaller grains are formed. Also, the surface of the titanium adhesion layer 158 which contacts the copper may promote small grain growth at selected anneal temperatures, such as at anneal process performed at 400° C.

Further, without being bound by the theory, it is believed that large grains 310 are formed in the bottom portion 220 due in part to the absence, or small amount, of titanium-copper alloy formation. Alloy formation from copper and titanium nitride occurs at temperatures greater than 450° C.; therefore, in an anneal process performed at a temperature less than 450° C., such as at 400° C., there is little titanium-copper alloy formation from the titanium nitride barrier layer 156. With little or no titanium-copper alloy formation, grain growth of copper is not suppressed. Also, the surface of the titanium nitride barrier layer 156 that forms the trench bottom surface 114 that contacts the copper may promote large grain growth at selected anneal temperatures, such as at anneal process performed at 400° C.

It is noted that the copper grain size growth rate is generally greatest at a free, non-confined surface, and in descending order, at a silicon oxide layer, at a tantalum nitride layer, at a titanium nitride layer, at a tantalum layer, and finally at a titanium layer having the smallest growth rate. Therefore, forming the trench 144 with titanium surrounding middle portion 230, with titanium nitride at the trench bottom surface 114 in bottom portion 220, and with an open, free surface adjacent the top portion 210, provides for forming the conductive TSV 200 with the Large-Small-Large grain size distribution shown in FIG. 22. More specifically, the top portion 210 may have the largest grain sizes, or largest average or mean grain size; bottom portion 220 may have the next largest grain sizes, or next largest average or mean grain size, and middle portion 230 may have the smallest grain sizes, or smallest average or mean grain size.

As noted above, before the anneal process, the conductive material 164 directly contacts the barrier layer 156 at the trench bottom surface 114, and the conductive material and/or seed layer 162 directly contacts the adhesion layer 158 along the trench sidewalls 112. Therefore, formation of the titanium-copper alloy may be greater along the trench sidewalls 112 than at the trench bottom surface 114.

FIG. 22 further illustrates that small voids 399 are formed in the middle portion 230. Specifically, after the thermal treatment, small voids 399 diffuse to the middle portion 230. As a result, the voids 399 may have little or no impact on device yield, unlike large void formation that may occur in other fabrication processes at bottom portion 220 and cause delamination.

Embodiments herein further provide for good adhesion between the copper conductive material 164 and the titanium nitride barrier layer 156 at the trench bottom surface 114. Further, embodiments herein use a re-sputter or ion etch process to increase coverage of trench sidewalls 112 with titanium material from the adhesion layer 158 removed from the trench bottom surface 114. Increased amounts of titanium on the trench sidewalls 112 in the bottom portion 220 improve adhesion and reduce delamination. Further, embodiments herein avoid barrier failure by using CVD-deposited titanium nitride as the barrier layer 156.

FIG. 24 is a schematic cross-section view focused on a trench sidewall 112 and the layers formed thereon before the anneal process is performed, such as at FIG. 16. FIG. 24 is a focused view of the trench sidewall 112, such as at top sidewall location 143, middle height sidewall location 142, or bottom sidewall location 141, as identified in FIG. 16.

As shown in FIG. 24, the insulating layer 152 is formed on the trench sidewall 112, the adhesion layer 154 is formed on the insulating layer 152 and has a thickness T1, the barrier layer 156 is formed on the adhesion layer 154 and has a thickness T2, and the adhesion layer 158 is formed on the barrier layer 156 and has a thickness T3.

Thicknesses T1, T2, and T3 may be measured after deposition of the layers 154, 156, and 158, and after the etch of layer 158 from the trench bottom surface, i.e., after operation S960 is performed.

In embodiments herein, the thicknesses T1, T2, and T3 may vary depending on the height of the location of measurement with respect to the trench bottom surface 114 (or depth with respect to the trench opening 111. It is noted that, at the bottom sidewall location 141, the thicknesses may be measured at a location of 5 m above the trench bottom surface 114, or at a location of 10% of the trench height above the trench bottom surface 114. Further, at the top sidewall location 143 adjacent to the trench opening 111, the thicknesses may be measured at a location of 1 m from the trench opening 111, or at a location of 2% of the trench height below the trench opening 111.

For example, at the bottom sidewall location 141 (and in the bottom portion 220 of the conductive via 200), thickness T1 may be from 1 nm to 10 nm, such as 2 nm. At the bottom sidewall location 141, thickness T1 may be at least 1 nm, at least 1.1 nm, at least 1.2 nm, at least 1.3 nm, at least 1.4 nm, at least 1.5 nm, at least 1.6 nm, at least 1.7 nm, at least 1.8 nm, at least 1.9 nm, or at least 2.0 nm. Further, at the bottom sidewall location 141, thickness T1 may be at most 10 nm, at most 9 nm, at most 8 nm, at most 7 nm, at most 6 nm, at most 5 nm, at most 4 nm, at most 3.5 nm, at most 3 nm, at most 2.9 nm, at most 2.8 nm, at most 2.7 nm, at most 2.6 nm, at most 2.5 nm, at most 2.4 nm, at most 2.3 nm, at most 2.2 nm, at most 2.1 nm, or at most 2 nm.

Further, at the bottom sidewall location 141 (and in the bottom portion 220 of the conductive via 200), thickness T2 may be from 15 nm to 40 nm, such as 25 nm. At the bottom sidewall location 141, thickness T2 may be at least 15 nm, at least 20 nm, at least 21 nm, at least 22 nm, at least 23 nm, at least 24 nm, at least 25 nm, at least 26 nm, at least 27 nm, or at least 30 nm. At the bottom sidewall location 141, thickness T2 may be at most 40 nm, at most 35 nm, at most 34 nm, at most 33 nm, at most 32 nm, at most 31 nm, at most 30 nm, at most 29 nm, at most 28 nm, at most 27 nm, at most 26 nm, or at most 25 nm.

Also, at the bottom sidewall location 141 (and in the bottom portion 220 of the conductive via 200), thickness T3 may be from 1 to 60 nm. In some embodiments, thickness T3 at the bottom sidewall location 141 is dependent on the critical dimension of the trench 144. For example, thickness T3 at the bottom sidewall location 141, measured in nanometers (nm), may be equal to or greater than 60,000 divided by the lateral critical dimension, measured in nanometers (nm), or equal to or greater than 60 divided by the lateral critical dimension, measured in micrometers (μm). Thus, for a critical dimension of from 1 to 10 micrometers (m), thickness T3 may be from 1 to 60 nm at the bottom sidewall location 141. Accordingly, for a critical dimension of 4 micrometers (μm), thickness T3 may be 15 nm at the bottom sidewall location 141.

In some embodiments, at the bottom sidewall location 141 (and in the bottom portion 220 of the conductive via 200), thickness T3 may be at least 1 nm, at least 2 nm, at least 3 nm, at least 4 nm, at least 5 nm, at least 6 nm, at least 7 nm, at least 8 nm, at least 9 nm, at least 10 nm, at least 12 nm, at least 14 nm, at least 16 nm, at least 18 nm, at least 20 nm, at least 22 nm, at least 24 nm, at least 26 nm, at least 27 nm, at least 30 nm, at least 32 nm, at least 34 nm, at least 36 nm, at least 38 nm, at least 40 nm, at least 42 nm, at least 44 nm, at least 46 nm, at least 48 nm, at least 50 nm, at least 52 nm, at least 54 nm, at least 56 nm, at least 58 nm, or at least 60 nm. In some embodiments, at the bottom sidewall location 141 (and in the bottom portion 220 of the conductive via 200), thickness T3 may be at most 80 nm, at most 70 nm, at most 65 nm, at most 60 nm, at most 58 nm, at most 56 nm, at most 54 nm, at most 52 nm, at most 50 nm, at most 48 nm, at most 46 nm, at most 44 nm, at most 42 nm, at most 40 nm, at most 38 nm, at most 36 nm, at most 34 nm, at most 32 nm, at most 30 nm, at most 28 nm, at most 26 nm, at most 24 nm, at most 22 nm, at most 20 nm, at most 18 nm, at most 16 nm, at most 14 nm, at most 12 nm, at most 10 nm, at most 9 nm, at most 8 nm, at most 7 nm, at most 6 nm, at most 5 nm, at most 4 nm, at most 3 nm, at most 2 nm, or at most 1 nm.

The thicknesses T1, T2, and T3 at the midlevel or middle height sidewall location 142 of the trench 144 (such as in the middle portion 230 of the conductive via 200) are generally greater than at the trench bottom surface 114.

For example, at the midlevel or middle height sidewall location 142 (such as in the middle portion 230 of the conductive via 200), thickness T1 may be from 6 nm to 20 nm, such as 12 nm. At the midlevel or middle height sidewall location 142, thickness T1 may be at least 6 nm, at least 8 nm, at least 9 nm, at least 10 nm, at least 11 nm, at least 12 nm, at least 13 nm, at least 14 nm, or at least 15 nm. Further, at the midlevel or middle height sidewall location 142, thickness T1 may be at most 20 nm, at most 18 nm, at most 16 nm, at most 15 nm, at most 14 nm, at most 13 nm, at most 12 nm, at most 11 nm, or at most 10 nm.

Further, at the midlevel or middle height sidewall location 142, thickness T2 may be from 20 nm to 35 nm, such as 27 nm. At the midlevel or middle height sidewall location 142, thickness T2 may be at least 20 nm, at least 22 nm, at least 24 nm, at least 25 nm, at least 26 nm, or at least 27 nm. Further, at the midlevel or middle height sidewall location 142, thickness T2 may be at most 35 nm, at most 30 nm, at most 29 nm, at most 28 nm, at most 27 nm, at most 26 nm, or at most 25 nm.

At the midlevel or middle height sidewall location 142 (such as in the middle portion 230 of the conductive via 200), thickness T3 may be from 40 nm to 80 nm, such as 60 nm. At the midlevel or middle height sidewall location 142, thickness T3 may be at least 40 nm, at least 45 nm, at least 50 nm, at least 55 nm, at least 56 nm, at least 57 nm, at least 58 nm, at least 59 nm, or at least 60 nm. Further, at the midlevel or middle height sidewall location 142, thickness T3 may be at most 80 nm, at most 75 nm, at most 70 nm, at most 65 nm, at most 64 nm, at most 63 nm, at most 62 nm, at most 61 nm, or at most 60 nm.

The thicknesses T1, T2, and T3 at the top sidewall location 143 adjacent to the trench opening 111 (such as in the top portion 210 of the conductive via 200) are generally greater than at the midlevel or middle height.

For example, at the top sidewall location 143 (such as in the top portion 210 of the conductive via 200), thickness T1 may be from 20 nm to 50 nm, such as 36 nm. At the top sidewall location 143, thickness T1 may be at least 20 nm, at least 25 nm, at least 30 nm, at least 31 nm, at least 32 nm, at least 33 nm, at least 34 nm, at least 35 nm, or at least 36 nm. At the top sidewall location 143, thickness T1 may be at most 50 nm, at most 45 nm, at most 40 nm, at most 39 nm, at most 38 nm, at most 37 nm, or at most 36 nm.

At the top sidewall location 143, thickness T2 may be from 15 nm to 50 nm, such as 30 nm. At the top sidewall location 143, thickness T2 may be at least 20 nm, at least 25 nm, at least 26 nm, at least 27 nm, at least 28 nm, at least 29 nm, or at least 30 nm. At the top sidewall location 143, thickness T2 may be at most 50 nm, at most 45 nm, at most 40 nm, at most 35 nm, at most 34 nm, at most 33 nm, at most 32 nm, at most 31 nm, or at most 30 nm.

At the top sidewall location 143, thickness T3 may be from 100 nm to 300 nm, such as 180 nm. At the top sidewall location 143, thickness T3 may be at least 100 nm, at least 125 nm, at least 150 nm, at least 175 nm, at least 180 nm, at least 200 nm, or at least 250 nm. At the top sidewall location 143, thickness T3 may be at most 300 nm, at most 250 nm, at most 225 nm, at most 200 nm, at most 190 nm, at most 180 nm, at most 160 nm, or at most 150 nm.

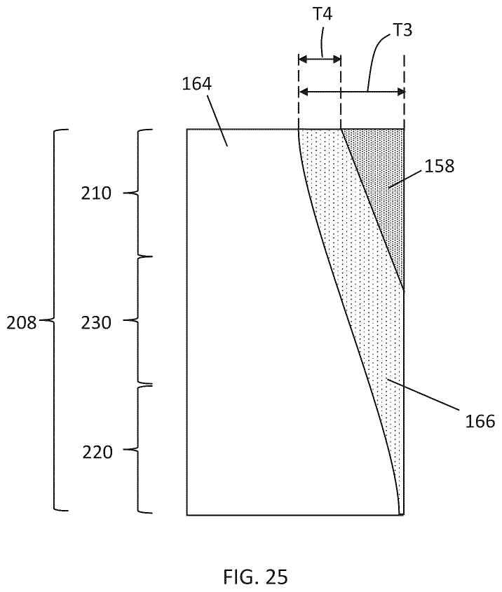

FIG. 25 is a cross-section view focused on a portion of the copper core 164, the adjacent adhesion layer 158, and the alloy 166 formed from performing the anneal process.

Specifically, FIG. 25 illustrates the formation of the alloy 166 at the interface of the conductive material 164 and the adhesion layer 158. For example, a titanium-copper alloy 166 may form between a copper conductive material 164 and a titanium adhesion layer 158. The amount of alloy 166 formed may be controlled by the temperature and duration of the anneal process. In some embodiments, the temperature of the anneal process is 400° C. and the duration of the anneal process is 30 minutes. In some embodiments, the anneal process is a hydrogen (H2) anneal process, i.e., performed with hydrogen.

As shown, the adhesion layer 158 is formed with a pre-anneal process lateral thickness T3, which varies along the height or depth 208 of the trench 144 and between portions 210, 220 and 230. During the anneal process, the alloy 166 is formed with a lateral thickness T4. Each lateral thickness T3 and T4 may vary along the height (or depth) 208 of the trench 144, as shown. As indicated, the pre-anneal lateral thickness T3 is greatest near the opening 111 of the trench 144 and is least at or near the trench bottom surface 114. At each height or depth 208 of the trench 144, pre-anneal thickness T3 is greater than or equal to thickness T4. In other words, all of, or less than all of, the adhesion layer 158 may be converted to alloy 166 at each height.

While FIG. 25 illustrates that a portion of the titanium adhesion layer 158 remains after the anneal process, particularly in the top portion 210, it is contemplated that all of the titanium adhesion layer 158 may be converted to titanium-copper alloy 166, such that T4=T3 in all locations along the height 208 of the conductive TSV 200.

Cross-referencing FIGS. 22, 24, and 25, in an embodiment, a conductive TSV 200 may include an adhesion layer 154 with a bottom sidewall thickness of 2 nanometers (nm), a midlevel sidewall thickness of 12 nanometers (nm), and a top sidewall thickness 36 nanometers (nm). The conductive TSV 200 may include a barrier layer 156 with a bottom sidewall thickness of 25 nanometers (nm), a midlevel sidewall thickness of 27 nanometers (nm), and a top sidewall thickness of 30 nanometers (nm). The conductive TSV 200 may be initially formed with an adhesion layer 158 with a bottom sidewall thickness of 2 nanometers (nm), a midlevel sidewall thickness of 12 nanometers (nm), and a top sidewall thickness of 36 nanometers (nm). The conductive TSV 200 may include an alloy layer 166 with a bottom sidewall thickness of 15 nanometers (nm), a midlevel sidewall thickness of 60 nanometers (nm), and a top sidewall thickness of 180 nanometers (nm). In other words, the adhesion layer 158 may be fully converted to alloy 166 at the bottom sidewall location and at the middle height sidewall location and may be partially converted to alloy 166 at the top sidewall location such that the adhesion layer 158 has a remaining top sidewall thickness of 60 nanometers (nm) in the conductive TSV 200.

While the above embodiments provide for formation of conductive TSVs 200 using suitable materials, an embodiment selects PVD-deposited titanium over PVD-deposited tantalum as each adhesive layer and selects CVD-deposited titanium nitride over CVD-deposited tantalum nitride or PVD-deposited tantalum nitride or PVD-deposited titanium nitride as the barrier layer.

It is noted that each adhesion layer should have good adhesion, and should suppress grain growth of the conductive material 164, i.e., copper, by forming an alloy with the conductive material 164. Further, the material of the adhesion layer should be easily etched, such as by the process of operation S960. PVD-deposited titanium has a material density of 4.5 g/cm³ and a relatively fast Ar etch rate, while a material with a high material density, such as 10 g/cm³ or higher, has a relatively slow Ar etch rate. Thus, PVD-deposited titanium has a high etch rate by the argon etch process of operation S960 at 10 A/s.

Copper grain suppression relates to the alloy formation temperature. For example, a lower alloy formation temperature relates to more alloy formation and suppresses copper grain growth. PVD-deposited titanium forms titanium-copper alloys at a relatively low temperature of above 300° C. Further, titanium promotes growth of small copper grains on titanium after an anneal at 400° C.

For adhesion to copper, metals are preferred to metal nitrides. Further, titanium is better than tantalum. Also, PVD-deposited titanium is better than CVD-deposited titanium due to less interface defects and impurities. Thus, PVD-deposited titanium has good adhesion to copper.

In addition, PVD-deposited titanium provides for 1 to 5% of sidewall bottom step coverage, and provides for 5 to 15% bottom step coverage. PVD-deposited titanium has poor barrier properties.

It is noted that the barrier layer should exhibit good barrier properties and good step coverage, and should be easily etched (or re-sputtered) such as by a PVD process with argon according to operation S960. CVD-deposited titanium nitride has a relatively low material density (g/cm³) of 4.5, and has a relatively fast Argon etch rate (at 10A/s).

CVD-deposited titanium nitride forms titanium-copper alloys at a relatively higher temperature of above 450° C. Further, CVD-deposited titanium nitride promotes growth of large copper grains on titanium nitride after an anneal at 400° C.

CVD-deposited titanium nitride exhibits poor copper adhesion.

CVD-deposited titanium nitride provides for greater than 90% of sidewall bottom step coverage, and provides for greater than 90% bottom step coverage. CVD-deposited titanium nitride has good barrier properties.

Further, in some embodiments, the method 900 provides for the optional formation of a PVD-deposited titanium outer adhesion layer 154, formation of a CVD-deposited metal nitride barrier layer 156, formation of a PVD-deposited metal inner adhesion layer 158, and an etch of the inner adhesion layer 158 from the trench bottom surface 114, such as by a PVD argon etch process.

Certain embodiments are performed without the optional PVD-deposited titanium outer adhesion layer 154. In such embodiments, the method includes formation of a CVD-deposited metal nitride barrier layer 156 on the trench sidewalls 112 and trench bottom surface 114, formation of a PVD-deposited metal inner adhesion layer 158, and an etch of the inner adhesion layer 158 from the trench bottom surface 114, such as by a PVD argon etch process.

In some embodiments, the method 900 provides for the formation of a PVD-deposited titanium outer adhesion layer 154, formation of a CVD-deposited titanium nitride barrier layer 156, formation of a PVD-deposited titanium inner adhesion layer 158, and an etch of the inner adhesion layer 158 from the trench bottom surface 114, such as by a PVD argon etch process.

In one embodiment, a conductive via includes a first end and a second end; a first portion adjacent to the first end; a second portion adjacent to the second; and a middle portion located between the first portion and the second portion, wherein the conductive via is included of metal grains, the metal grains in the first portion have a first grain size; the metal grains in the second portion have a second grain size; the metal grains in the middle portion have a third grain size; the first grain size is greater than the third grain size; and the second grain size is greater than the third grain size.

In some embodiments, the conductive via has a critical dimension of from 1 to 10 micrometers (μm).

In some embodiments, the conductive via has an aspect ratio of from 5 to 20.

In some embodiments, the first grain size is greater than the second grain size.

In some embodiments, the first grain size is a maximum grain size, and wherein the maximum grain size is from 200 to 1000 nanometers (nm).

In some embodiments, the first end is distanced from the second end by a height; the first portion, the second portion, and the middle portion each have a subheight equal to ⅓ of the height; the first portion has an average grain size of greater than 0.5 of the maximum grain size; the second portion has an average grain size of greater than 0.5 of the maximum grain size; and the middle portion has an average grain size of less than 0.5 of the maximum grain size.

In some embodiments, the first portion has an average grain size of greater than 0.6 of the maximum grain size; the second portion has an average grain size of less than 0.6 of the maximum grain size; and the middle portion has an average grain size of less than 0.4 of the maximum grain size.

In another embodiment, a method for forming a metal structure in a trench is provided and includes depositing a barrier layer along sidewalls and a bottom surface of the trench; depositing a metal layer over the barrier layer, wherein the metal layer is formed with a vertical thickness over the bottom surface of the trench and with a decreasing sidewall thickness along the sidewalls from an opening of the trench toward the bottom surface of the trench; removing the metal layer from the bottom surface of the trench; and forming a metal in the trench.

In some embodiments, the method further includes depositing an adhesion layer along the sidewalls and the bottom surface of the trench, wherein the barrier layer is deposited over the adhesion layer, and wherein the adhesion layer is formed with a vertical thickness over the bottom surface of the trench and with a decreasing sidewall thickness along the sidewalls from an opening of the trench toward the bottom surface of the trench.

In some embodiments of the method, the trench has a lateral critical dimension; the adhesion layer has a first lateral thickness (T1) at a selected height over the bottom surface; the first lateral thickness (T1) is greater than 2 nanometers (nm); the barrier layer has a second lateral thickness (T2) at the selected height; the second lateral thickness (T2) is greater than 25 nanometers (nm); the metal layer has a third lateral thickness (T3) at the selected height; and the third lateral thickness (T3), measured in nanometers (nm), is greater than or equal to 60,000 divided by the lateral critical dimension, measured in nanometers (nm).

In some embodiments of the method, depositing the adhesion layer includes depositing titanium with a physical vapor deposition (PVD) process; depositing the barrier layer include depositing titanium nitride with a chemical vapor deposition (CVD) process; depositing the metal layer includes depositing titanium with a physical vapor deposition (PVD) process; and removing the metal layer from the bottom surface of the trench includes performing an ion etching process.

In some embodiments of the method, removing the metal layer from the bottom surface of the trench includes re-depositing metal layer material onto the sidewalls of the trench.

In some embodiments, the method further includes depositing an insulation liner in the trench, wherein depositing the barrier layer includes depositing the barrier layer over the insulation liner.

In some embodiments of the method, forming the metal in the trench includes depositing a seed layer over the metal layer; and depositing a metal fill over the seed layer; and the method further includes performing an anneal process to grow metal grains from the seed layer and the metal fill with a desired grain distribution.

In another embodiment, a semiconductor device includes: a metal interconnection including: a copper core; and a titanium-copper alloy surrounding the copper core.

In some embodiments of the semiconductor device, the copper core includes copper grains; the copper core includes a top portion, a bottom portion, and middle portion between the top portion and the bottom portion; the copper grains in the top portion have a first average grain size; the copper grains in the bottom portion have a second average grain size; the copper grains in the middle portion have a third average grain size; the first average grain size is greater than the third average grain size; and the second average grain size is greater than the third average grain size.

In some embodiments of the semiconductor device, the metal interconnection further includes a titanium layer surrounding the titanium-copper alloy at the top portion of the copper core.

In some embodiments of the semiconductor device, the metal interconnection further includes a titanium nitride layer surrounding the titanium-copper alloy below the top portion of the copper core and surrounding the titanium layer at the top portion of the copper core.

In some embodiments of the semiconductor device, the metal interconnection further includes a titanium nitride layer surrounding the titanium-copper alloy.

In some embodiments of the semiconductor device, the metal interconnection further includes an outer titanium layer surrounding the titanium nitride layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A conductive via comprising:
a first end and a second end;
a first portion adjacent to the first end;
a second portion adjacent to the second; and
a middle portion located between the first portion and the second portion,
wherein the conductive via is comprised of metal grains,
wherein the metal grains in the first portion have a first grain size;
wherein the metal grains in the second portion have a second grain size;
wherein the metal grains in the middle portion have a third grain size;
wherein the first grain size is greater than the third grain size; and
wherein the second grain size is greater than the third grain size.

2. The conductive via of claim 1, wherein the conductive via has a critical dimension of from 1 to 10 micrometers (μm).

3. The conductive via of claim 1, wherein the conductive via has an aspect ratio of from 5 to 20.

4. The conductive via of claim 1, wherein the first grain size is greater than the second grain size.

5. The conductive via of claim 1, wherein the first grain size is a maximum grain size, and wherein the maximum grain size is from 200 to 1000 nanometers (nm).

6. The conductive via of claim 5, wherein:
the first end is distanced from the second end by a height;
the first portion, the second portion, and the middle portion each have a subheight equal to ⅓ of the height;
the first portion has an average grain size of greater than 0.5 of the maximum grain size;
the second portion has an average grain size of greater than 0.5 of the maximum grain size; and
the middle portion has an average grain size of less than 0.5 of the maximum grain size.

7. The conductive via of claim 6, wherein:
the first portion has an average grain size of greater than 0.6 of the maximum grain size;
the second portion has an average grain size of less than 0.6 of the maximum grain size; and
the middle portion has an average grain size of less than 0.4 of the maximum grain size.

8. A method for forming a metal structure in a trench, the method comprising
depositing a barrier layer along sidewalls and a bottom surface of the trench;
depositing a metal layer over the barrier layer, wherein the metal layer is formed with a vertical thickness over the bottom surface of the trench and with a decreasing sidewall thickness along the sidewalls from an opening of the trench toward the bottom surface of the trench;
removing the metal layer from the bottom surface of the trench; and
forming a metal in the trench.

9. The method of claim 8, further comprising:
depositing an adhesion layer along the sidewalls and the bottom surface of the trench, wherein the barrier layer is deposited over the adhesion layer, and wherein the adhesion layer is formed with a vertical thickness over the bottom surface of the trench and with a decreasing sidewall thickness along the sidewalls from an opening of the trench toward the bottom surface of the trench.

10. The method of claim 9, wherein:
the trench has a lateral critical dimension;
the adhesion layer has a first lateral thickness (T1) at a selected height over the bottom surface;
the first lateral thickness (T1) is greater than 2 nanometers (nm);
the barrier layer has a second lateral thickness (T2) at the selected height;
the second lateral thickness (T2) is greater than 25 nanometers (nm);
the metal layer has a third lateral thickness (T3) at the selected height; and
the third lateral thickness (T3), measured in nanometers (nm), is greater than or equal to 60,000 divided by the lateral critical dimension, measured in nanometers (nm).

11. The method of claim 9, wherein:
depositing the adhesion layer comprises depositing titanium with a physical vapor deposition (PVD) process;
depositing the barrier layer comprise depositing titanium nitride with a chemical vapor deposition (CVD) process;
depositing the metal layer comprises depositing titanium with a physical vapor deposition (PVD) process; and
removing the metal layer from the bottom surface of the trench comprises performing an ion etching process.

12. The method of claim 8, wherein removing the metal layer from the bottom surface of the trench comprises re-depositing metal layer material onto the sidewalls of the trench.

13. The method of claim 8, further comprising depositing an insulation liner in the trench, wherein depositing the barrier layer comprises depositing the barrier layer over the insulation liner.

14. The method of claim 8, wherein forming the metal in the trench comprises:
depositing a seed layer over the metal layer; and
depositing a metal fill over the seed layer; and
wherein the method further comprises performing an anneal process to grow metal grains from the seed layer and the metal fill with a desired grain distribution.

15. A semiconductor device comprising:
a metal interconnection comprising:
a copper core; and
a titanium-copper alloy surrounding the copper core.

16. The semiconductor device of claim 15, wherein:
the copper core is comprised of copper grains;
the copper core includes a top portion, a bottom portion, and middle portion between the top portion and the bottom portion;
the copper grains in the top portion have a first average grain size;
the copper grains in the bottom portion have a second average grain size;
the copper grains in the middle portion have a third average grain size;
the first average grain size is greater than the third average grain size; and
the second average grain size is greater than the third average grain size.

17. The semiconductor device of claim 16, wherein the metal interconnection further comprises a titanium layer surrounding the titanium-copper alloy at the top portion of the copper core.

18. The semiconductor device of claim 17, wherein the metal interconnection further comprises a titanium nitride layer surrounding the titanium-copper alloy below the top portion of the copper core and surrounding the titanium layer at the top portion of the copper core.

19. The semiconductor device of claim 17, wherein the metal interconnection further comprises a titanium nitride layer surrounding the titanium-copper alloy.

20. The semiconductor device of claim 19, wherein the metal interconnection further comprises an outer titanium layer surrounding the titanium nitride layer.
